(19) United States
(12) Patent Application Publication
(10) Pub. No.: US 2003/0168095 A1
(43) Pub. Date: Sep. 11, 2003

(54) Self powered solar generator

(76) Inventor: Robert William Jackson, Hinton, OK (US)

Correspondence Address: Robert William Jackson, RR 2 Box 142, Hinton, OK, 73047, US

(21) Appl. No.: 10/211,041

(22) Filed: Aug. 2, 2002

Related U.S. Application Data
(60) Provisional application No. 60/363,271, filed on Mar. 11, 2002.
(60) Provisional application No. 60/368,394, filed on Mar. 29, 2002.

(51) Int. Cl. H01L 31/00

(52) U.S. Cl. 136/244; 136/291

(57) ABSTRACT

This device is a specially designed sealed compartment with a highly reflective or mirrored interior.

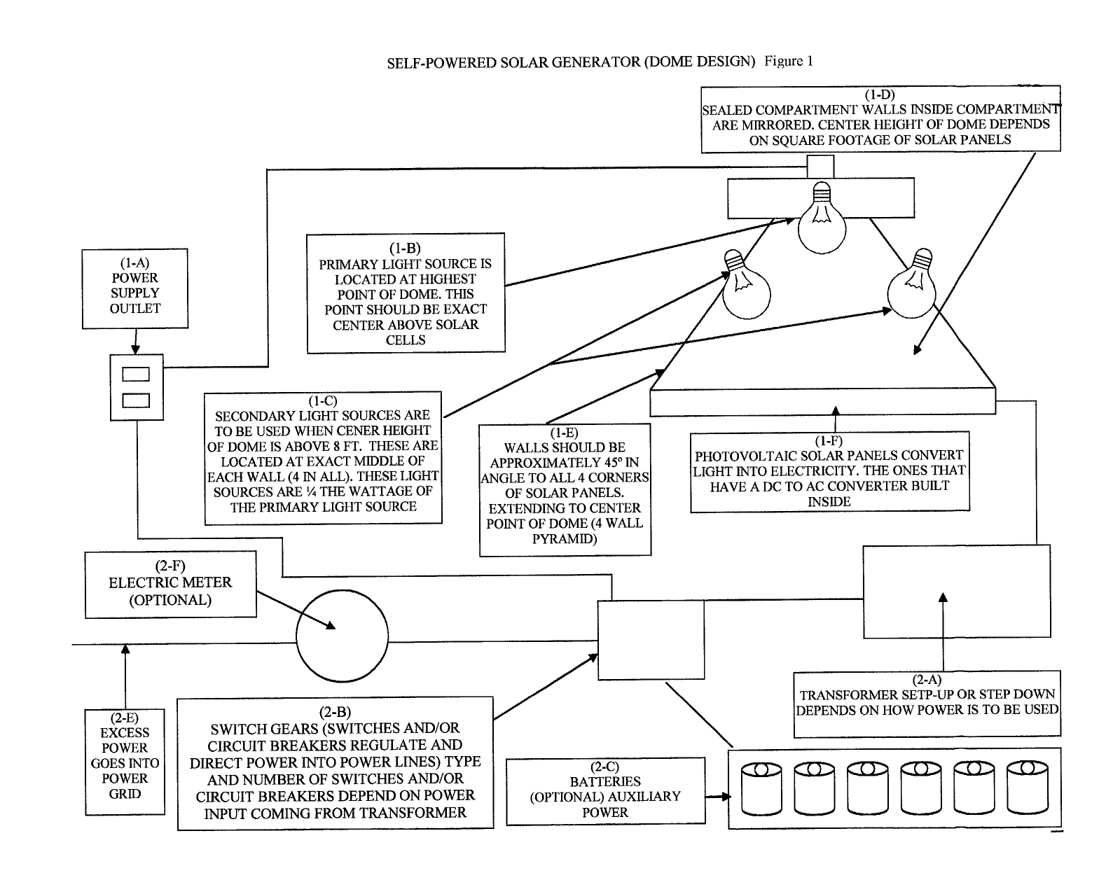

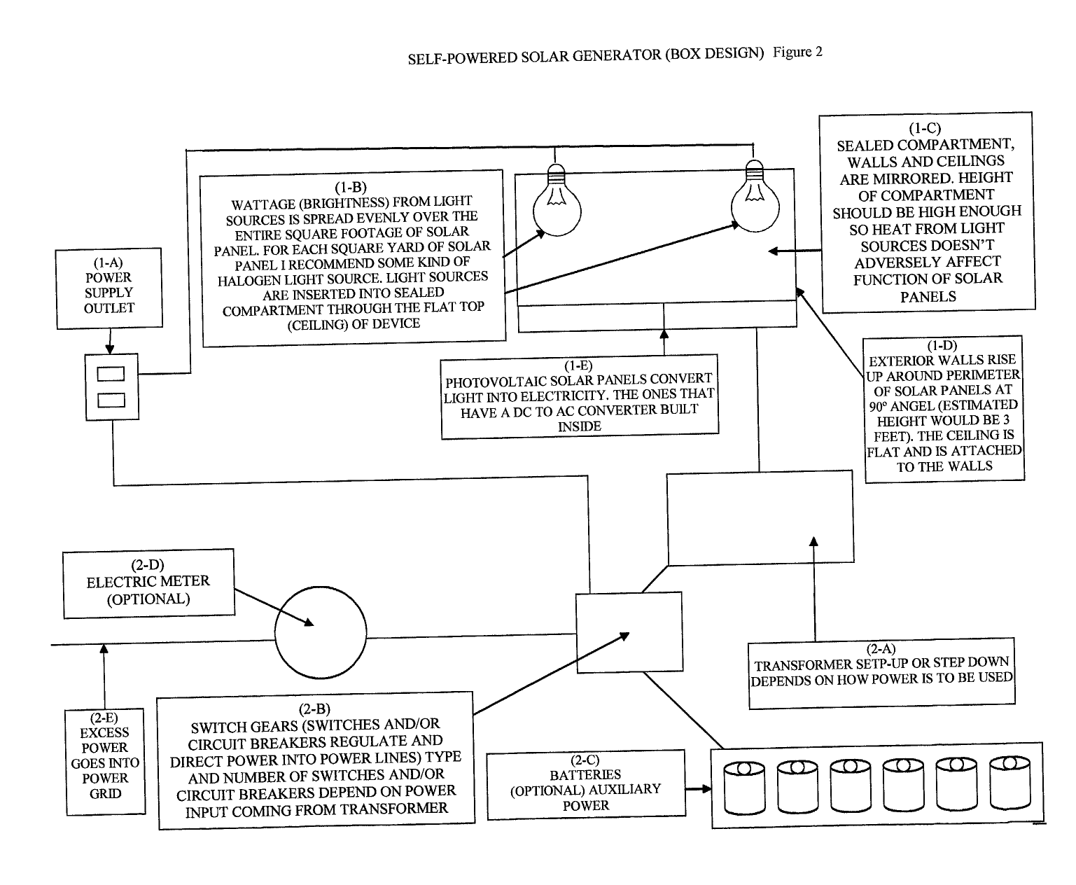

This device is designed to create brightness (wattage) in the most efficient manner using electric light. This light is then converted into electricity by the most efficient photovoltaic solar panels and or solar cells available. The theory is you can generate more electric power than what it takes to power the device.

### REFERENCE TO SEQUENCE LISTING, A TABLE, OR A COMPUTER PROGRAM LISTING COMPACT DISK APPENDIX

Table for Dome Design Concept
This Table is a basic estimation for the general guidelines for
the overall function of this device. The most efficient ratios
would require actual testing which I hope to do in the near future
power output is unknown.

| Number of | | | | |
|---|---|---|---|---|
| square yards | | Wattage of | Wattage of | Approximate |
| photovoltaic | Center | Primary | Each Second- | to power |
| solar | Height of | Light | ary Light | light |
| panels | Dome | Source | Source | sources |
| 1 | 3 Ft | 150 Watts | | 1.2 Amps |
| 2 | 4 Ft | 200 Watts | | 1.6 Amps |
| 3 | 5 Ft | 300 Watts | | 2.5 Amps |
| 4 | 6 Ft | 400 Watts | | 3.25 Amps |
| 5 | 7 Ft | 500 Watts | | 4.6 Amps |
| 6 | 8 Ft | 600 Watts | 150 Watts | 6.25 Amps |
| 7 | 9 Ft | 700 Watts | 175 Watts | 7.25 Amps |
| 8 | 10 Ft | 800 Watts | 200 Watts | 8.25 Amps |
| 9 | 11 Ft | 900 Watts | 225 Watts | 9.25 Amps |
| 10 | 12 Ft | 1000 Watts | 250 Watts | 10 Amps |

### BACKGROUND OF INVENTION

This theory was developed by Robert William Jackson. I claim to be the original inventor of this concept. This is a renewable energy device using basic solar principals.

My idea is to use light that is generated in the most efficient manner possible using electricity. The theory is to create maximum brightness (watts). This light is then converted into electricity using the most efficient photovoltaic solar panels for this particular purpose.

The basic theory is to create at least 1,000 watts of brightness per square yard of solar panel and or solar cells. I believe you can achieve this and use between 1 to 1.5 amps of power. This can be achieved by use of mirrors and other reflective components. The design of the device is very important.

I believe for each amp of power used you can generate approximately 1,000 watts of brightness which is spread evenly over each square yard of solar panels and or solar cells.

The solar panels need to be able to generate at least 150 watts of power if they receive 1,000 watts of light per square yard.

I came up with this idea while reading a book entitled “Exploring Power Mechanics” author Harold T. Glenn, copyright 1967. He claims that the sun creates 1,000 watts of light per square yard on a sunny day. He claimed the silicon photovoltaic solar panels in use during this time period would create 150 watts of electricity. I thought to myself that if solar panels operate from wattage from sunlight why couldn't they operate from wattage generated from electric sources. I have searched the Internet for any information on this theory and found nothing that deals with this concept.

The standards for solar-panels deal with sunlight. I definitely need to do more research, but I have found out there is not much information out there.

I hope to be able to test my concept and get some kind of basic ratio. Watts created (brightness) to watts generated (electricity). The higher t he potential power output (wattage) of the solar panels directly relates to power potential of device.

The theory is to create the most brightness (wattage) possible with the least amount of energy to power the light sources.

For optimum results, the solar panels and or solar cells need to operate at their full potential. The panels on the market today only convert approximate 20% of the wattage they receive. Example, if they receive 1,000 watts they produce approximately 200 watts of electricity.

Any improvements to solar panels that increase this percentage directly increases power output potential, of my device and makes my concept that more feasible.

I think this concept has enormous potential due to the fact there is no moving parts and is very low maintenance.

I feel the following information is relevant to this application because I'm trying to explain the lack of information known to me. Besides the fact there's not much information on this subject. I'm reluctant in seeking assistance due to the negative results I received on two prior patents when I tried to get any information and some major problems I've encountered on getting a prototype built and tested.

This is my third attempt at doing a patent. The other 2 patents are awaiting review. Patent 10/136521 (Self-Powered Hydro-Electric Generator) May 1, 2002 with the support of provisional patent 60/363271 Mar. 11, 2002. The other one is patent No. 10/136063 May 1, 2002 (Air-Driven Electric Generator) with the support of provisional patent No. 60/368394 Mar. 29, 2002.

This is my third attempt at a high efficiency power generator patent. One was with water, one was with air and now light.

I've encountered the exact problem on all 3 concepts. I can't find any information that pertain to my ideas and honestly believe they haven't been tried.

This time I'm trying to get this application submitted before I seek any assistance as with my 2 prior patents I feel pressured to submit my patent as soon as I can due to the possibility the secrecy of my idea may have been compromised.

### BRIEF SUMMARY OF THE INVENTION

I claim with my concept you can generate more electricity than what it takes to power my device.

My device uses electric light that is contained in a specially designed mirrored compartment. This light is directed into the most advanced photovoltaic solar panels for this purpose.

I have two designs for the contained mirrored compartment which is very important to my overall concept. The dome design (4 walls at approximately 45° degree angles which converge at a point that is located above the exact middle of device) a 4 wall pyramid. I also have what I call a box design.

I also have an arch design but I would need professional help to draw up these plans, which I hope to do in the near future.

### BRIEF DESCRIPTION OF THE SEVERAL VIEWS OF THE DRAWINGS

My two drawings are two examples of how my overall concept works. I feel with these two drawings there isn't a need for side views because they would be same as the front views.

### SHEET 1 DRAWING (DOME DESIGN)

1-A—is the power supply outlet

1-B—primary light source

1-C—secondary light source (These lights should only be used if my theory proves them feasible to increate over all power output)

1-D—Sealed Compartment with highly reflective interior (example mirrored)

1-E—Basic design dimensions

1-F—The base of device is completely covered with photovoltaic solar panels and or solar cells

2-A—Transformer increases or decreases the voltage

2-B—Switchgears—I use this term in a broad sense. This is where the electricity is regulated and distributed through switches and or circuit breakers. When dealing with low voltage fuses could be used

2-C—Batteries—excess power could be stored in batteries. I list them as optional as an auxiliary power source. They could be used as a primary power source with this concept. (This is how most solar systems operate now)

2-D—Electric meter is used to measure electric power going into the power grid and any power that might come in from power grid

2-E—Amount of excess power going into the power grid

### BRIEF DESCRIPTION OF BOX DESIGN DRAWING SHEET 2 OF DRAWINGS

1-A—is the power supply outlet

1-B—light sources

1-C—sealed compartment with highly reflective interior (examples mirrored)

1-D—Exterior wall dimensions

1-E—photovoltaic solar panels and or solar cells these cover the entire base of this device

2-A—transformer increase or decrease the voltage

2-B—switchgears. I use this term in a broad sense. This is where the electricity is regulated and distributed through switches and or circuit breakers when dealing with low voltage fuses could be used.

2-C—batteries—excess power could be stored in batteries. I list them as optional as an auxiliary power source. They could be used as a primary power source. They could be used as a primary power source with this concept. (This is how most solar systems operate now)

2-D—electric meter is used to measure electric power going into the power grid and any power that might come in from power grid

2-E—amount of excess power going into the power grid

### DETAILED DESCRIPTION OF INVENTION “Dome Design”

The power used to operate primary light source (See 1-A sheet 1) depends on type and wattage of primary light source (See 1-B sheet 1).

The primary light source is located at highest point inside a sealed compartment (See 1-B sheet 1). The walls inside compartment are mirrored (See 1-D sheet 1). There are four walls and each has approximately a 45° angle (See 1-E sheet 1). They extend from all four corners of solar panels which cover the entire base of the device (See 1-F sheet 1). The walls extend to center point of the dome. This point is above the exact middle of device. This is also the point where primary light source is located (See 1-B Sheet 1). This is a four wall pyramid design (See 1-E Sheet 1). The center height of dome depends on square footage of solar panels. See Table on page 2 for approximate dimensions for the most efficient operation of device. The chart is my own estimations and intended to show general guidelines for my concept.

The wattage of primary light source (See 1-B sheet 1) depends on square footage of solar panels and or solar cells (see 1-F sheet 1). See Table on page 2 for approximate ratio. Basically wattage of primary light source increases by 100 watts per additional square yard of solar panels and or solar cells. I think halogen type lighting would work well with this concept. Type T-3 lamps are all I have to work with right now. These type J double ended lamps put out extreme brightness for the power they use.

Basically the center height of dome increases by one foot for each additional square yard of solar panel and/or solar cells. The dimension starts at 3 ft. center height for 1 square yard (9 square feet) of solar panel and or solar cells. See Table on page 2 for approximate ratio.

When center height of dome is above 8 feet (6 square yards of solar panels and or solar cells) I would employ secondary light sources which are located at exact middle of each wall. These light sources (4 in all) are approximately ¼ the wattage of the primary light source (see 1-C sheet 1) also see Table on page 2 for approximate ratio. These lights should only be used if my theory proves them feasible to increate overall power output. This means these light sources need to generate more power than that which it takes to power them.

The Table on page 2 is basic estimations. It would take prototype testing to get the best ratio.

The possibilities of the different combinations of light sources, solar cells, and design of devices would require extensive study for the most efficient designs.

I hope in the near future to draw up more precise drawings. I have a design plan for multiple domes being connected together fore a larger power output. This would create one large sealed compartment. I would need professional help in drawing this up. I have a lot of design ideas. My box design is my most basic. In my opinion I think it would be a very efficient design.

“Box Desing”

The light sources need to be spaced evenly above the solar panels and or solar cells. (See 1-B sheet 2). The design calls for a 500 watt halogen T-3 lamp located over exact middle of each square yard of solar panel and or solar cells which cover the entire floor of device (see 1-E sheet 2). The light sources should be approximately three feet above solar panels. (High enough where heat from light sources doesn't impede the solar panels function.) The walls should approximately be this same height. (See 1-D sheet 2). The compartment needs to be as compact as much as possible. This increases brightness (wattage) of light sources.

The power used to operate the light sources depends on type and number of the light sources (See 1-A sheet 2).

The walls are located around perimeter of the solar panels and or solar cells at 90° angles. The ceiling is flat and is attached to all four walls (See 1-D sheet 2).

Inside the sealed compartment the walls and ceiling are mirrored. The light sources are recessed slightly into the ceiling. (See 1-B sheet 2)

I realize that solar panels in use today create D.C. (direct current) power which for the most part is stored in batteries. I have drawn up my plans using solar panels which have a D.C. to A.C. (alternating current) converter built inside of them. Believe any power that goes into the power grid should be AC power. This could be done outside of the solar panels but with my limited electrical knowledge I chose the following diagram. This is the same diagram I've used on all three of my patents. The only difference is the type of electric generators (my concepts). What happens to the electricity after it leaves the generator has been difficult for me to research. I've done my best to try to explain my overall concept and hope its sufficient.

The electricity that the solar panels and or solar cells generate with my concept is directed into a transformer which decrease or increase the voltage see (2A sheet 1 and 2). Either way electricity that comes form the transformer is directed into some kind of switch gear device (See 2-B sheet 1 and 2). This device regulates and directs the electric power. An electric meter of some sort could be used to measure the amount of electricity that comes from switch gear device (See 2-B sheet 1 and 2). This excess power goes into power grid through power line (see 2-E sheet 1 and 2) and or stored in batteries (See 2-C Sheet 1 and 2).

The device does require initial start-up. There are a lot of ways of doing this from batteries (See 2-B sheet 1 and 2) gasoline generators or from any standard power source (See 1-A sheet 1 and 2).

[image]

1. What I claim as my invention is that using electric light as a power source and this power source is in a sealed compartment that has highly reflective or mirrored interior. This light is then converted into electricity by the most efficient photovoltaic solar panels and/or solar cells available.

2. I claim with my device that photovoltaic solar panels could be used at anytime to generate electricity.

3. I claim you can use different kinds of electric lighting with this concept.

4. I claim I should be given patent protection for this concept even if a more efficient type solar cell or solar panel is developed.

5. I claim different designs for this device could be developed for which I should be compensated if this should happen.

6. I claim you can use different kinds of existing photovoltaic solar panels and/or solar cells with this concept.

7. I claim as long as you follow my basic concept as describing this patent application that the only restriction to power output is the size of the device.

8. I claim utilities, industry, households, or anywhere you can use electricity can generate electricity with this concept.

9. I claim this is a highly efficient and clean way of generating electricity.

10. I claim an electric hybrid car could be developed with this concept as an electric power source.
